(19) United States
(12) Patent Application Publication
(10) Pub. No.: US 2025/0183572 A1
(43) Pub. Date: Jun. 5, 2025

(54) GOLD FINGER CONNECTOR AND MEMORY STORAGE DEVICE

(71) Applicant: PHISON ELECTRONICS CORP., Miaoli (TW)

(72) Inventors: Chin-Hsun Wang, Chiayi County (TW); Yong Lin Chen, New Taipei City (TW); Jen Chieh Wang, Taichung City (TW); Yen-Wen Tseng, Miaoli County (TW)

(73) Assignee: PHISON ELECTRONICS CORP., Miaoli (TW)

(21) Appl. No.: 18/415,686

(22) Filed: Jan. 18, 2024

(30) Foreign Application Priority Data
Dec. 1, 2023 (TW) 112146755

(51) Int. Cl. H01R 13/04; H01R 13/646

(52) U.S. Cl. CPC H01R 13/04; H01R 13/646; H01R 2201/06

(57) ABSTRACT

A gold finger connector and memory storage device having the same. The gold finger connector includes a connector body; a plurality of ground pins; and at least one signal shielding structures, disposed on a first ground pin of the plurality of ground pins, wherein the at least one first signal shielding structure is connected to the outside of a first side of an extension part of the first ground pin and electrically conducts at least two layers of the first ground pin.

### CROSS-REFERENCE TO RELATED APPLICATION

This application claims the priority benefit of Taiwan application serial no. 112146755, filed on 1 Dec. 2023. The entirety of the above-mentioned patent application is hereby incorporated by reference herein and made a part of this specification.

### BACKGROUND

### Technical Field

The present invention relates to a connector structure and, in particular, to a gold finger connector and memory storage device.

### Description of Related Art

Some types of memory storage devices are configured with a gold finger connector to communicate with a host system via pins on the gold finger connector. However, the pins on the gold finger connector are in close proximity to each other and can easily interfere with each other during signal transmission.

### SUMMARY

The present invention provides a gold finger connector and memory storage device that suppress electrical interference between some of the pins on the gold finger connector and each other.

Example embodiments of the present invention provide a gold finger connector comprising a connector body; a plurality of grounding pins; and at least one first signal shielding structure disposed on a first grounding pin of the plurality of grounding pin, wherein the at least one first signal shielding structures are connected to an outer of a first side of an extension portion of the first grounding pin and electrically conduct to at least two layers of the first grounding pin.

Example embodiments of the present invention further provide a memory storage device that includes: a gold finger connector; a rewritable non-volatile memory modules; and a memory control circuit unit electrically connected to the gold finger connector and the rewritable nonvolatile memory module. The gold finger connector comprises: a connector body; a plurality of grounding pins provided on a first surface of the connector body, wherein each grounding pin has a plurality of layers; and at least one first signal shielding structures, disposed on a first grounding pin of the plurality of grounding pins, wherein the at least one first signal shielding structures are connected to an outer of a first side of an extension portion of the first grounding pin and electrically conduct to at least two layers of the first grounding pin.

Based on the foregoing, the gold finger connector and the memory storage device provided in this example embodiment includes a connector body; a plurality of grounding pins; and a plurality of signal shielding structures, wherein the plurality of grounding pins are disposed on the first surface of the connector body, wherein each grounding pin has a plurality of layers. The plurality of signaling shielding structures disposed on the outer of a side of the extension portion of the plurality of grounding pins, and electrically conducting the plurality of layers of the grounding pins, so as to suppress electrical interference between neighboring pins on gold finger connectors.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic view of the appearance of a gold finger connector according to an exemplary embodiment of the present invention.

FIG. 1B is a partially enlarged view of FIG. 1A depicted according to an exemplary embodiment of the present invention.

FIG. 1C is a main view and top view of the partially enlarged portion of the gold finger connector of FIG. 1A depicted according to an exemplary embodiment of the present invention.

FIG. 2 is a schematic diagram depicting top views for respective layer plans of a grounding pin of a gold finger connector according to an exemplary embodiment of the present invention.

FIG. 3A is a schematic diagram depicting grounding pins and signal shielding structures respectively disposed on the grounding pins according to an example embodiment of the present invention.

FIGS. 3B-3D are schematic diagrams depicting grounding pins, signaling pin(s) and signal shielding structures respectively disposed on the grounding pins according to an example embodiment of the present invention.

FIGS. 4A-4C are schematic diagrams depicting various number of signal shielding structures respectively disposed on the grounding pins according to an example embodiment of the present invention.

FIG. 4D is a schematic diagram of a signal frequency versus the resulted resonance strength according to an exemplary embodiment of the present invention.

FIG. 5 is a block schematic diagram of a memory storage device according to an exemplary embodiment of the present invention.

FIG. 6A is a side view schematic diagram depicting a signaling shielding structure disposed on an outer of a first side of a first grounding pin to connect all the layers of the first grounding pin according to an example embodiment of the present invention.

FIG. 6B is a top view schematic diagram depicting a signaling shielding structure disposed on the outer of the first side of the first grounding pin to connect all of the layers of the first grounding pin according to an example embodiment of the present invention.

FIG. 7A is a side view schematic diagram depicting a plurality of signaling shielding structures disposed on an outer of a first side of a first grounding pin to connect multiple group of layers of the first grounding pin according to an example embodiment of the present invention.

FIG. 7B is a top view schematic diagram depicting a plurality of signaling shielding structures disposed on an outer of a first side of a first grounding pin to connect multiple group of layers of the first grounding pin according to an example embodiment of the present invention.

FIG. 8A is a side view schematic diagram depicting a signal shielding structure disposed on an outer of a first side of a first grounding pin to cover completely and connect all the layers of the first grounding pin according to an example embodiment of the present invention.

FIG. 8B is a top view schematic diagram depicting a signal shielding structure disposed on an outer of a first side of a first grounding pin to cover completely and connect all the layers of the first grounding pin according to an example embodiment of the present invention.

### DESCRIPTION OF THE EMBODIMENTS

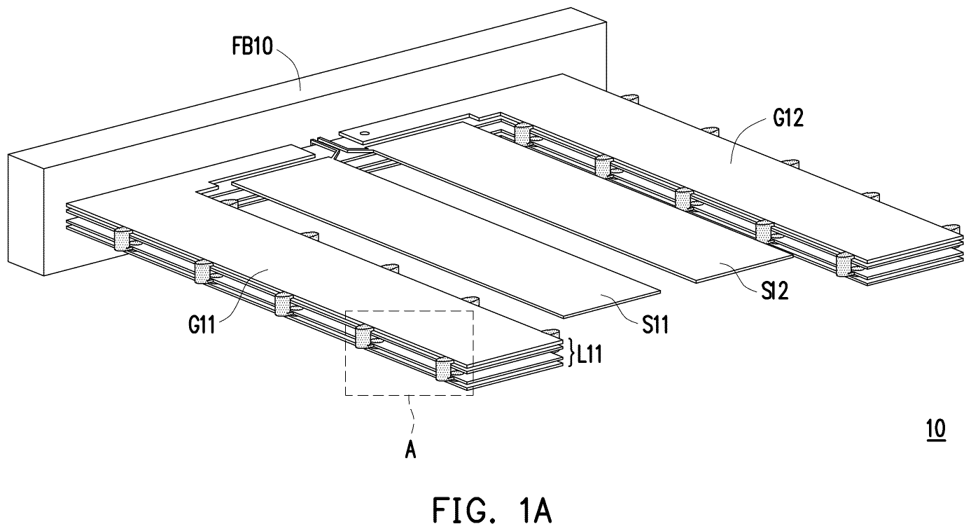

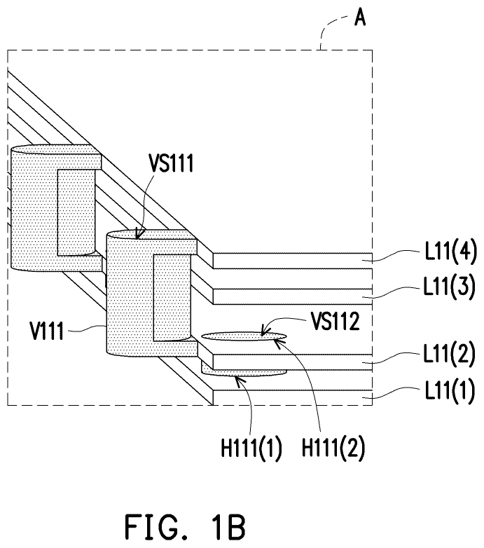

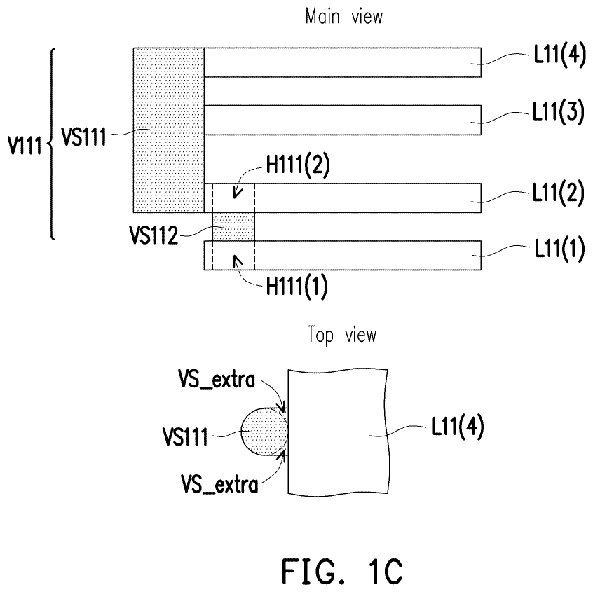

FIG. 1A is a schematic view of the appearance of a gold finger connector according to an exemplary embodiment of the present invention. FIG. 1B is a partially enlarged view of FIG. 1A depicted according to an exemplary embodiment of the present invention. FIG. 1C is a main view and top view of the partially enlarged portion of the gold finger connector of FIG. 1A depicted according to an exemplary embodiment of the present invention. Referring to FIG. 1A, the gold finger connector 10 includes a connector body FB10, grounding pins G11, G12, signaling pins S11, S12, and a signal shielding structures (e.g., signal shielding structure Viii shown in gray in FIG. 1B). The connector body FB10 can be used to accommodate, for example, a controller chip, circuit board, or various electronic circuits that perform signal processing of the gold finger connector 10. It should be reminded that the present invention is not limited to the number of pairs of grounding pins G11, G12 and signaling pins S11, S12 shown in FIG. 1A, i.e., the total number of grounding pins and signaling pins may be adjusted according to the practical requirements, and the present invention does not limit them. The material of the grounding pin and the signaling pin may be metal or any conductor material. The relative position, distance and configuration dimensions between the grounding pin and the signaling pin may conform to the setup specifications of the respective interface, without limitation of the present invention. The grounding pin is used to provide a reference ground voltage. The signaling pin is used to transmit a data signal.

The grounding pins G11, G12 and the signaling pins S11, S12 are disposed on the same surface (also called as first surface) of the connector body FB10. The signaling pins S1, S12 are disposed between the grounding pins G11, G12.

The grounding pins G11, G12 respectively have a plurality of layers (e.g., a plurality of layers L11 of the grounding pin). A signal shielding structure is disposed(provided) on an outer of an extension portion of the grounding pin to connect the plurality of layers of the grounding pin to which the signal shielding structure belongs.

In an exemplary embodiment, when the gold finger connector 10 is inserted into a slot of a another matching electronic device with the grounding pins and signaling pins provided, at least a portion of that grounding pins and at least a portion of the signaling pins are electrically connected to other pins in the slot. In this state, these mutually electrically connected pins can be used to transmit signals between the connected electronic device and the connector body FB10/gold finger connector 10.

Referring to FIGS. 1B and 1C, in this example, the grounding pin G11 includes four layers L11(1)˜L11(4), and one of signal shielding structures (V111) is disposed on an outer of a side(edge) of the grounding pin G11 to connect the layers L11(1)˜L11(4) to electrically conduct all of the layers L11(1)˜L11(4) of the grounding pin G11. In more detail, the signal shielding structure V111 is a metal structure (or a conductive structure) comprising a metal stick VS111 (also called as a first metal stick) and a metal stick VS112 (also called as a second metal stick).

The upper surface of the metal stick VS111 is flushed with the upper surface of the layer L11(4) and is connected to the first side of layer L11(4) with the help of an auxiliary portion VS_extra outside the cylindrical portion of the metal stick VS111. The degree of connection can be strengthened with the help of the auxiliary part VS_extra. The metal stick VS111 extends downwardly and is connected to the first side of the layers L11(3) and L11(2), wherein the lower surface of the metal stick VS111 is flush with the lower surface of the layer L11(2), and is connected to the first sides of the layer L11(2) with the help/support of the auxiliary portion VS_extra, which is outside the cylindrical portion of the metal stick VS111. The first sides of the layers L11(1) and L11(2) respectively have conduction holes H111(1) and H111(2). The metal stick VS112 is connected to the conduction holes H111(1) and H111(2). In addition, the metal stick VS111 is also connected to the layer L11(3).

In the above-described connection relationship between the signal shielding structure V111 and the plurality of layers L11(1)˜L11(4) as exemplary. In another embodiment, the layers L11(4)˜L11(1) are all connected to the metal stick VS111. In another embodiment, the signal shielding structure V111 has only a metal stick VS111, which is directly connected to the outer surface of the first side of the plurality of layers L11(1)˜L11(4).

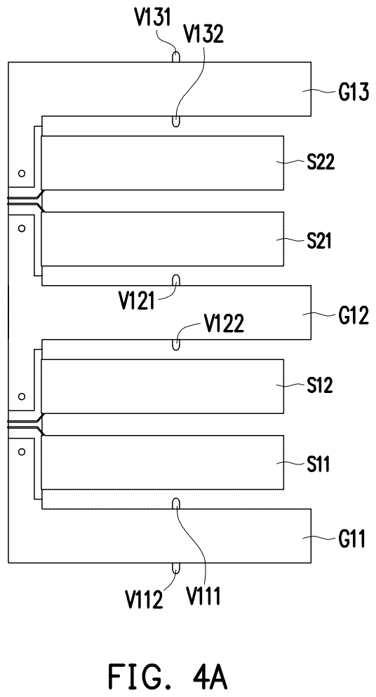

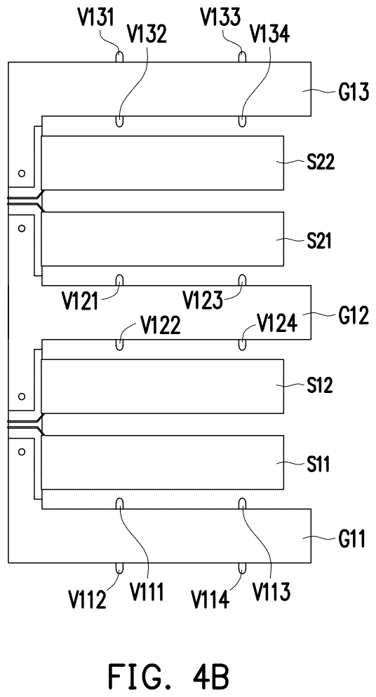

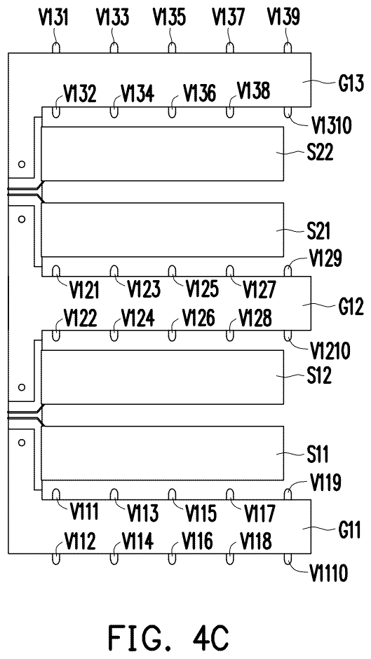

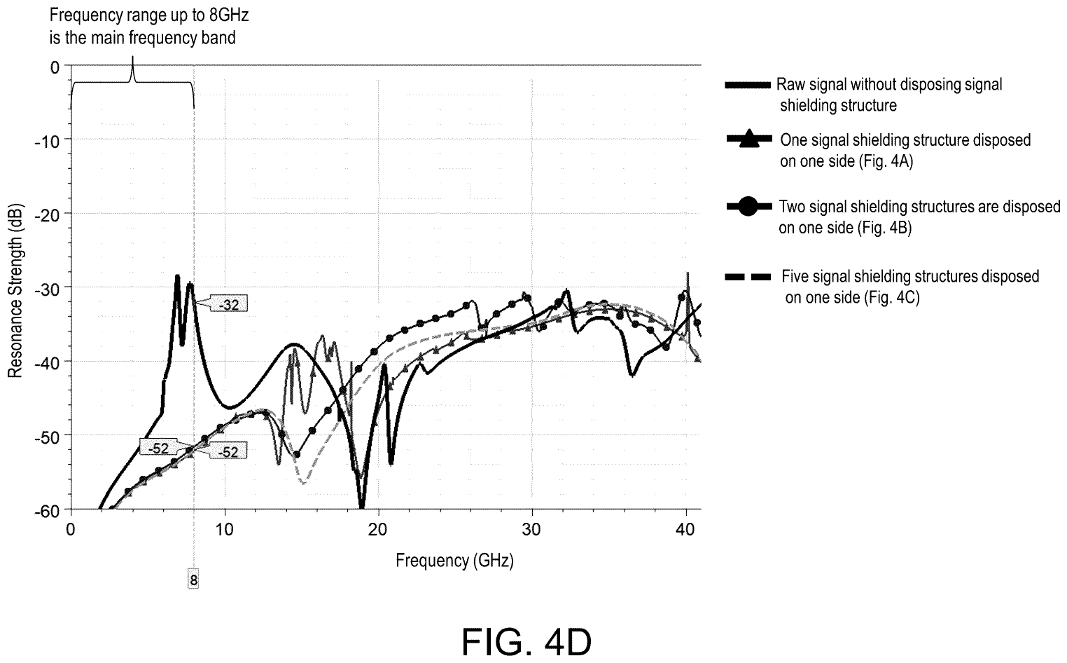

Traditionally, electrical interference (resonance) between each group of signaling pins (or between signaling pins and other circuit components) can easily occur due to close proximity. This electrical interference may seriously affect the signal quality and stability of the transmitted data signals. Accordingly, in the provided example embodiment, the strength of electrical interference that may be generated is suppressed by providing at least one signal shielding structure at least on the outer of the side, facing an adjacent signaling pin, of the grounding pin. For example, as shown in FIG. 4A, the signal shielding structures V111-V132 may assist in suppressing electrical interference generated between a first set of signaling pins S11, S12 and a second set of signaling pins S21, S22, as well as electrical interference generated between the signaling pins S11˜S22 and other neighboring circuit components.

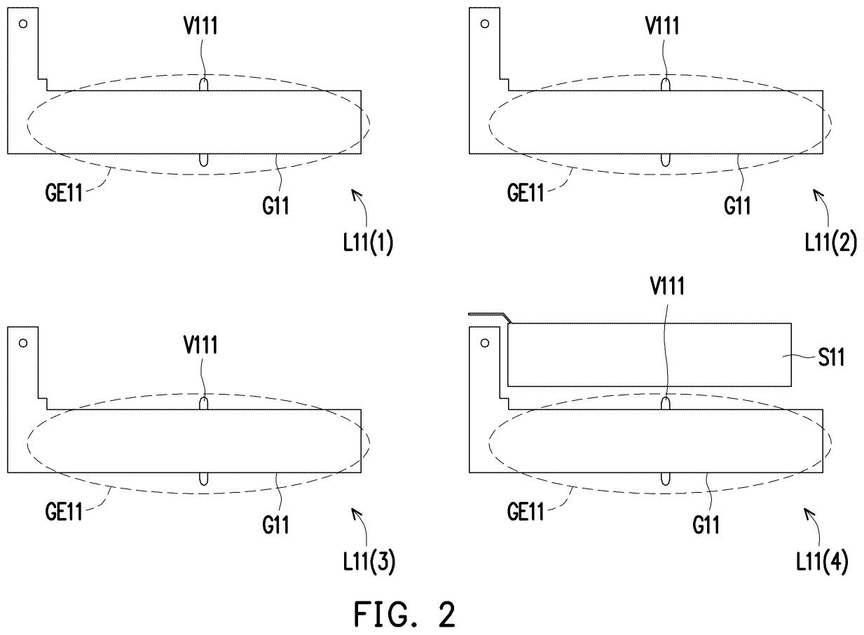

FIG. 2 is a schematic diagram depicting top views for respective layer plans of a grounding pin of a gold finger connector according to an exemplary embodiment of the present invention. Referring to FIG. 2, in the case of the first grounding pin G11, for example, a signal shielding structure V111 may be disposed on the outer of the first side of the extension portion GE11 of the first grounding pin G11, and this signal shielding structure V111 connects to all the layers (also referred to as grounding layers) L11(1) to L11(4) of the first grounding pin G11 together. As shown in FIG. 2, the same signal shielding structure V111 is disposed on the outer of the first side of layers L11(1) through L11(4), in this example, layer L11(4) is the uppermost layer, and signaling pin S11 corresponds to layer L11(4).

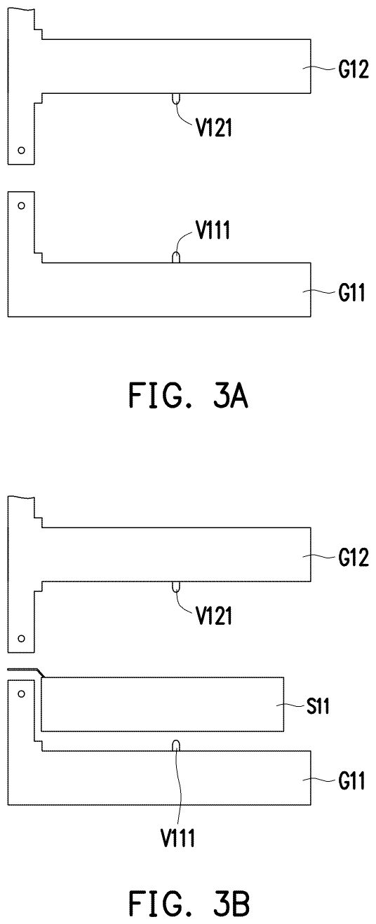

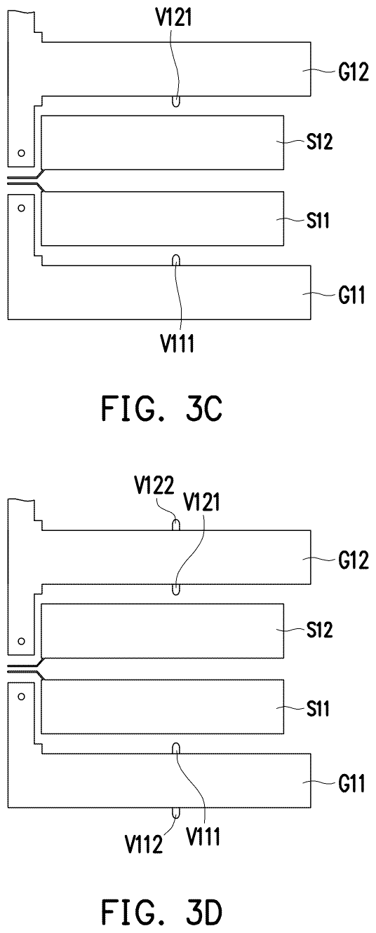

FIG. 3A is a schematic diagram depicting grounding pins and signal shielding structures respectively disposed on the grounding pins according to an example embodiment of the present invention. Referring to FIG. 3A, in this embodiment, a signal shielding structure Viii (also referred to as a first signal shielding structure) is disposed on an outer of a first side of a first grounding pin G11 and electrically conducts a plurality of layers of that first grounding pin G11. In addition, that first side of the first grounding pin G11 faces a second side of an extension portion of the second grounding pin G12, wherein the signal shielding structure V121 (also referred to as a second signal shielding structure) is disposed on that second grounding pin G12, is connected to an outer of that second side of that second grounding pin G12, and electrically conducts that plurality of layers of that second grounding pin G12.

FIGS. 3B-3D are schematic diagrams depicting grounding pins, signaling pin(s) and signal shielding structures respectively disposed on the grounding pins according to an example embodiment of the present invention.

Referring to FIG. 3B, in this embodiment, a first signaling pin S11 is provided between such first grounding pin G11 and such second grounding pin G12. A first side of the first signaling pin S11 is faced by the second side, on which the at least one second signal shielding structures V121 are disposed, of the second grounding pin G12. A second side of the first signaling pin S11 is faced by the first side, on which the at least one first signal shielding structures V111 are provided, of the first grounding pin G11. That is, the first grounding pin G11 and the second grounding pin G12 are disposed with signal shielding structures V111, V121 respectively on the outer of the sides facing the first signaling pin S11.

Referring to FIG. 3C, in this embodiment, in addition to the first signaling pin S11, a second signaling pin S12 is provided between the first signaling pin S11 and the second grounding pin G12. The first grounding pin G11 and the second grounding pin G12 are disposed with signal shielding structures V111, V121 on the outer of the sides facing the first signaling pin S11 and the second signaling pin S12, respectively.

Referring to FIG. 3D, in this embodiment, the gold finger connector 10 further includes a signal shielding structure V112 (also referred to as a third signal shielding structure) which is disposed on the outer of a further first side, opposite to the first side (provided with the signal shielding structure V111), of the first grounding pin G11. Similarly, a signal shielding structure V122 which is disposed on the outer of a further second side, opposite to the second side (provided with the signal shielding structure V121), of the second grounding pin G12. That is, in addition to the side facing the neighboring signaling pin, the other (opposite) side of the grounding pin that does not face the neighboring signaling pin may be further provided with a signal shielding structure to shield/suppress electrical interference from other circuits/electronic devices.

FIGS. 4A-4C are schematic diagrams depicting various number of signal shielding structures respectively disposed on the grounding pins according to an example embodiment of the present invention.

Referring to FIG. 4A, in this embodiment, one signal shielding structure may be disposed on each side of each of the grounding pins G11˜G13 to suppress the strength of the resonance due to signaling interference from the signaling pins S11˜S22. For example, signal shielding structures V111, V112 are disposed on grounding pin G11; signal shielding structures V121, V122 are disposed at grounding pin G12; and signal shielding structures V131, V132 are disposed at grounding pin G13.

Referring to FIG. 4B, in this embodiment, two signal shielding structures may be disposed on each side of each of the grounding pins G11˜G13 to suppress the strength of the resonance due to signaling interference from the signaling pins S11˜S22. For example, signal shielding structures V111 to V114 are disposed at grounding pin G11; signal shielding structures V121 to V124 are disposed at grounding pin G12; and signal shielding structures V131 to V134 are disposed at grounding pin G13.

Referring to FIG. 4C, in this embodiment, five signal shielding structures may be disposed on each side of each of the grounding pins G11˜G13 to suppress the strength of the resonance due to signaling interference from the signaling pins S11˜S22. For example, signal shielding structures V111 to V1110 are disposed at grounding pin G11; signal shielding structures V121 to V1210 are disposed at grounding pin G12; and signal shielding structures V131 to V1310 are disposed at grounding pin G13.

It should be noted that the present invention does not limit distance between two neighboring signal shielding structures on the same side, and the total number of signal shielding structures provided on each side. The distance and the total number may be appropriately adjusted depending on the process complexity and the signal specification requirements.

FIG. 4D is a schematic diagram of a signal frequency versus the resulted resonance strength according to an exemplary embodiment of the present invention.

In this embodiment, the primary frequency band of the data signal is below 8 GHz. As can be seen in FIG. 4D, without disposing any signal shielding structure (raw signal), the resonance strength of the primary frequency band is as high as −30 dB (getting stronger as it gets closer to 0 dB). However, by adding one or more signal shielding structures, the measured resonance strength in the main frequency band is suppressed to below −50 dB. That is, as shown in FIG. 4D, the signal shielding structure provided by the example embodiment of the present invention effectively reduces the strength of electrical interference, such that the quality and stability of the data signals transmitted by the gold finger connector 10 are improved.

In an exemplary embodiment, the gold finger connector 10 of FIG. 1 may be incorporated into a memory storage device to improve the quality of signals transmitted via a connection interface, implemented via the gold finger connector 10, within the memory storage device.

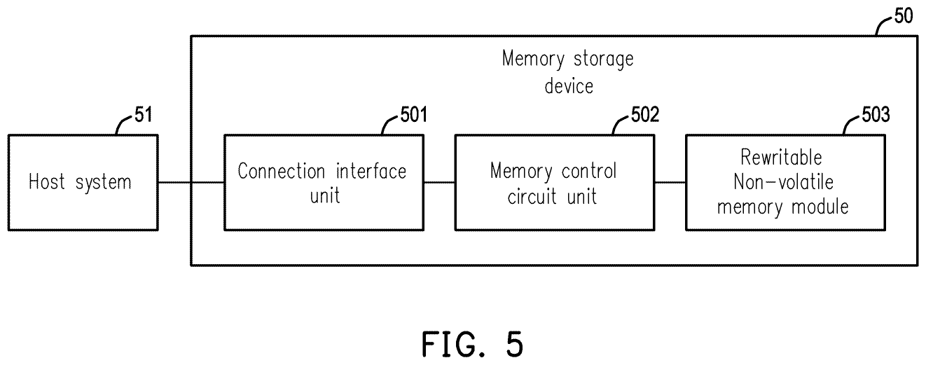

FIG. 5 is a block schematic diagram of a memory storage device according to an exemplary embodiment of the present invention. Referring to FIG. 5, the memory storage device 50 includes a connection interface unit 501, a memory control circuit unit 502, and a rewritable non-volatile memory module 503.

A connection interface unit 501 is configured to couple the memory storage device 50 to the host system 51. For example, the connection interface unit 501 may include the gold finger connector 10 of FIG. 1. The memory storage device 50 may communicate with the host system 51 via the connection interface unit 501. For example, the interface unit 501 may be compatible with the Peripheral Component Interconnect Express (PCI Express) standard, the Serial Advanced Technology Attachment (SATA) standard, Parallel Advanced Technology Attachment (PATA) standard, Institute of Electrical and Electronic Engineers (IEEE) 1394 standard, Universal Serial Bus (USB) standard, SD interface standard, Ultra High Speed-I (UHS-I) interface standard, Ultra High Speed-II (UHS-II) interface standard, Memory Stick (MS) interface standard, MCP interface standard, MMC interface standard, eMMC interface standard, Universal Flash Storage (UFS) interface standard, eMCP interface standard, CF interface standard, Integrated Device Electronics (IDE) standard, or other suitable data standard.

Memory control circuit unit 502 is coupled to connection interface unit 501 and rewritable non-volatile memory module 503. Memory control circuit unit 502 is configured to execute multiple logic gates or control commands implemented in hardware or firmware and to write, read, and erase data in rewritable non-volatile memory module 503 based on instructions from host system 51. In an example implementation, the memory control circuit unit 502 may include a flash memory controller.

The rewritable non-volatile memory module 503 is used to store data written by the host system 51. For example, the rewritable non-volatile memory module 503 may include a Single Level Cell (SLC) NAND flash memory module (i.e., a flash memory module that stores one bit in a memory cell), a Multi Level Cell (MLC) NAND flash memory module (i.e., a flash memory module that stores two bits in a memory cell), a Triple Level Cell (TLC) NAND flash memory module (i.e., a flash memory module that stores three bits in a memory cell), a Quad Level Cell (QLC) NAND flash module (i.e., a flash memory module that can store 4 bits in a memory cell), other flash memory modules, or other memory modules with the same or similar characteristics.

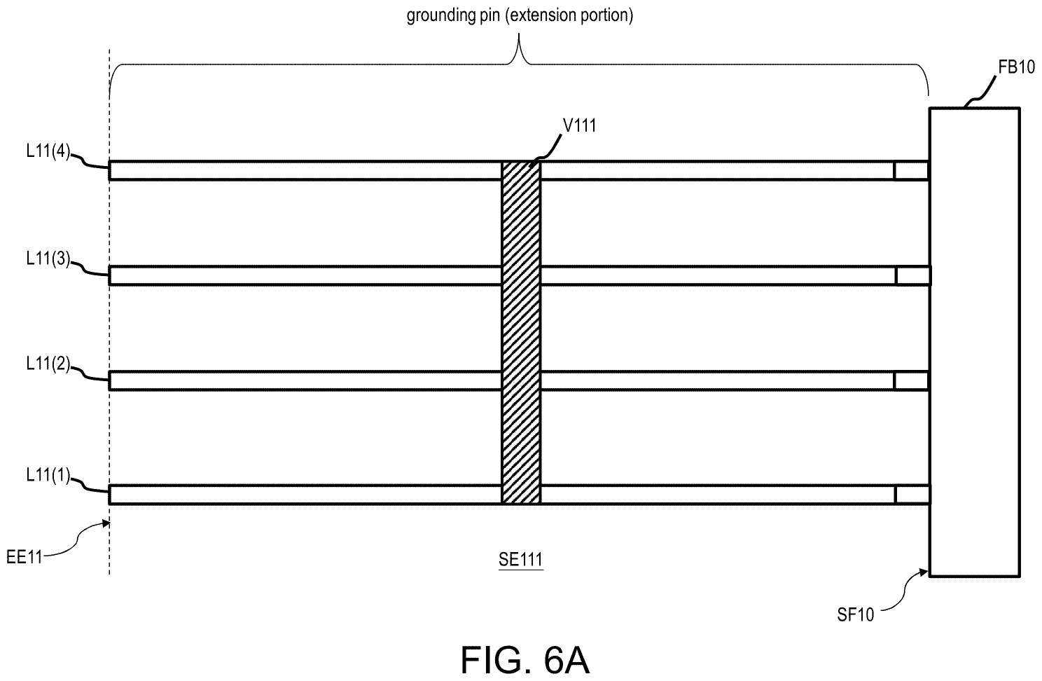

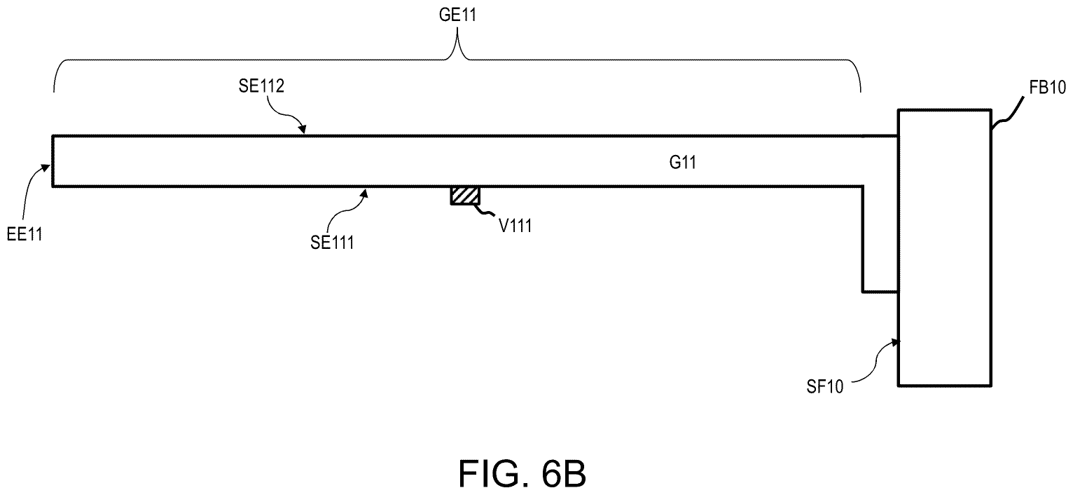

FIG. 6A is a side view drawn toward a view angle of the first side SE111 of the first grounding pin G11, and FIG. 6B is an aerial view of the first grounding pin G11. Referring also to FIGS. 6A and 6B, in this embodiment, the first grounding pin G11 is disposed on the first surface SF10 of the connector body FB10. The multiple layers L11(1)˜L11(4) of the first grounding pin G11 are layers parallel to each other, wherein layer L11(4) is a metal sheet, also called as a finger, and wherein layer L11(1)˜L11(3) is a PCB sheet, also called as GND layers. Layers L11(1)˜L11(4) are connected to each other. The plurality of layers are vertically projected into/within the same projecting area, and the first side SE111 of the first grounding pin G11 includes the first side SE111 of each of the plurality of layers. It should be noted that in this embodiment, the vertical projection of the signaling shielding structure V111 is not within that projecting area of the vertical projections of the plurality of layers L11(1) to L11(4), but it may be noted that the signaling shielding structure V111 is located (connected) at the outer of the first side SE111 of the extension portion GE11 of the first grounding pin G11. By doing so, it can be avoided that the additionally provided signal shielding structure accidentally affects the original performance of the gold finger connector 10. In addition, damage to the upper surface of the metal sheet of layer L11(4) can also be avoided.

Furthermore, in this embodiment, only one signal shielding structure V111 is disposed on the outer of the first side SE111 of the extension portion GE11 of the first grounding pin G11. No signal shielding structure is disposed on the outer of the further first side SE112 of the extension portion GE11 of the first grounding pin G11. The signal shielding structure V111 is connected to the first side SE111 of all layers L11(1)˜L11(4) at the same time as the first grounding pin G11. The upper surface of the signal shielding structure V111 does not extend beyond the upper surface of the uppermost layer L11(4), and the lower surface of the signal shielding structure V111 does not extend beyond the lower surface of the lowermost layer L11(1). That is, the signal shielding structure V111 covers a first side SE111 of each of the plurality of layers L11(1)˜L11(4) and the signal shielding structure V111 does not extend beyond a horizontal projecting range, toward the first side SE111, of the plurality of layers L11(1)˜L11(4).

Similar to the example of FIG. 6A, in another embodiment, a number of signal shielding structures V111 disposed on the outer of the first side SE111 of the extension portion GE11 of the first grounding pin G11 is greater than one, and each of the signal shielding structures V111 covers a first side SE111 of each of the plurality of layers L11(1) to L11(4) and does not extend beyond a horizontal projecting range, toward the first side SE111, of the plurality of layers L11(1) to L11(4).

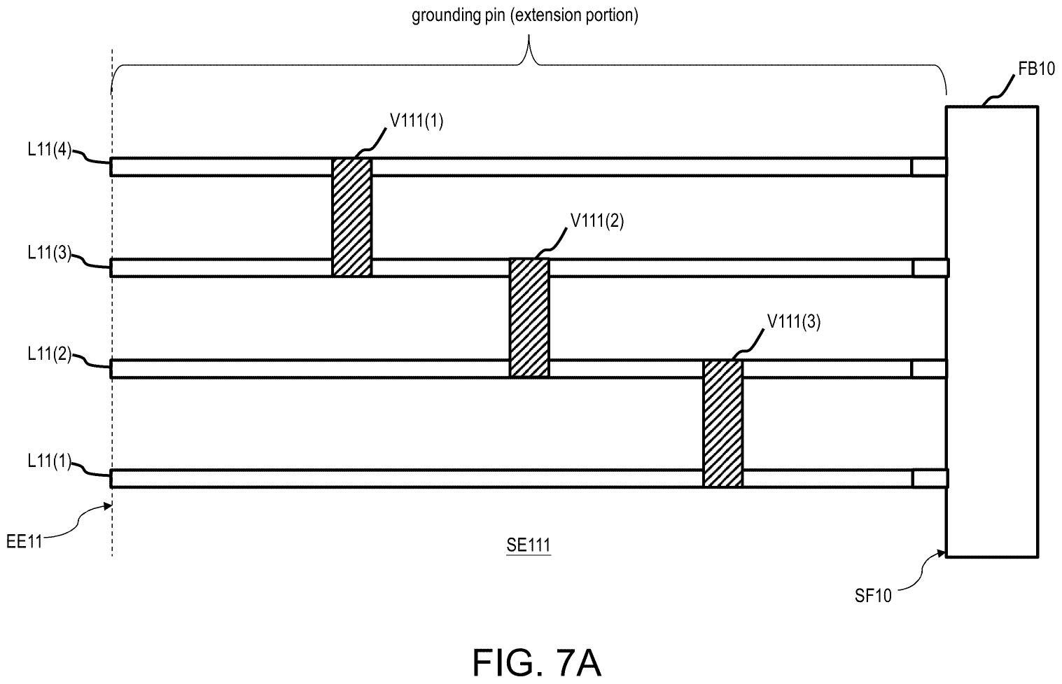

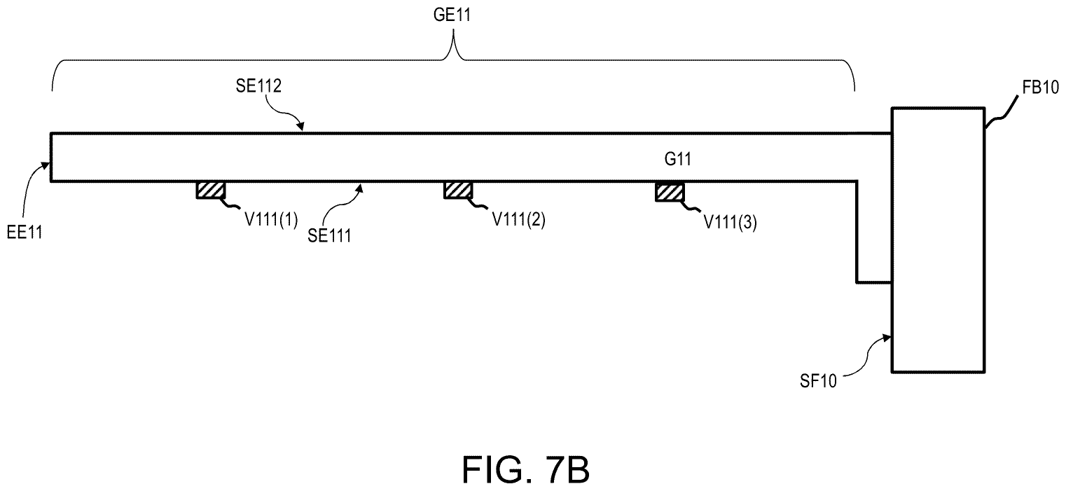

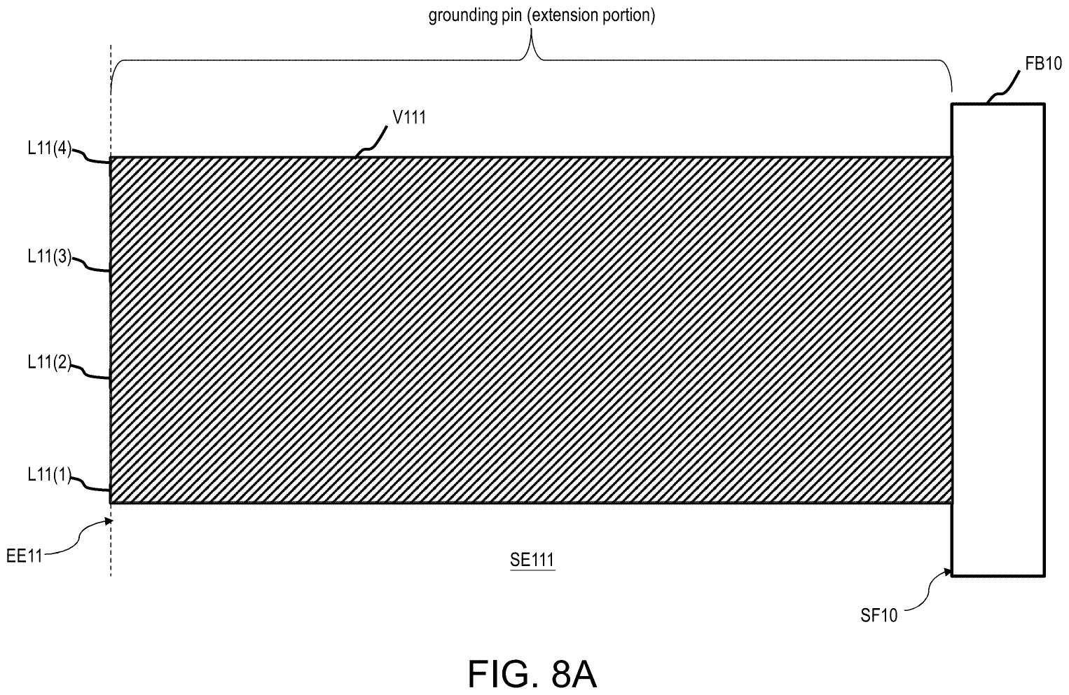

FIG. 7A is a side view schematic diagram depicting a plurality of signaling shielding structures disposed on an outer of a first side of a first grounding pin to connect multiple group of layers of the first grounding pin according to an example embodiment of the present invention. FIG. 7B is a top view schematic diagram depicting a plurality of signaling shielding structures disposed on an outer of a first side of a first grounding pin to connect multiple group of layers of the first grounding pin according to an example embodiment of the present invention.

Referring also to FIGS. 7A, 7B, in this embodiment, a plurality of first signaling shielding structures V111(1)˜V111(3) are disposed on the outer of such first side SE111 of the first grounding pin G11, wherein each of the first signaling shielding structures V111 electrically conducts a plurality of layers (a set/group of layers) of such first grounding pin G11. That is, this embodiment differs from the embodiments of FIGS. 6A and 6B in that, in this embodiment, each of the signal shielding structures V111(1)˜(3) is not connected to all of the layers L11(1)˜L11(4). For example, signal shielding structure V111(1) connects layers L11(3), L11(4); signal shielding structure V111(2) connects layers L11(2), L11(3); signal shielding structure V111(3) connects layers L11(1), L11(2).

It should be noted that the present invention is not limited to the connection patterns of the above embodiments. In other embodiments, the number of layers of the grounding layer and the connection position of each signal shielding structure provided on the outer side of the grounding pin may be adjusted as desired. For example, for a grounding pin having 4 layers, there may be a signal shielding structure on the outer side for connecting all the layers, and another signal shielding structure for connecting 3 layers.

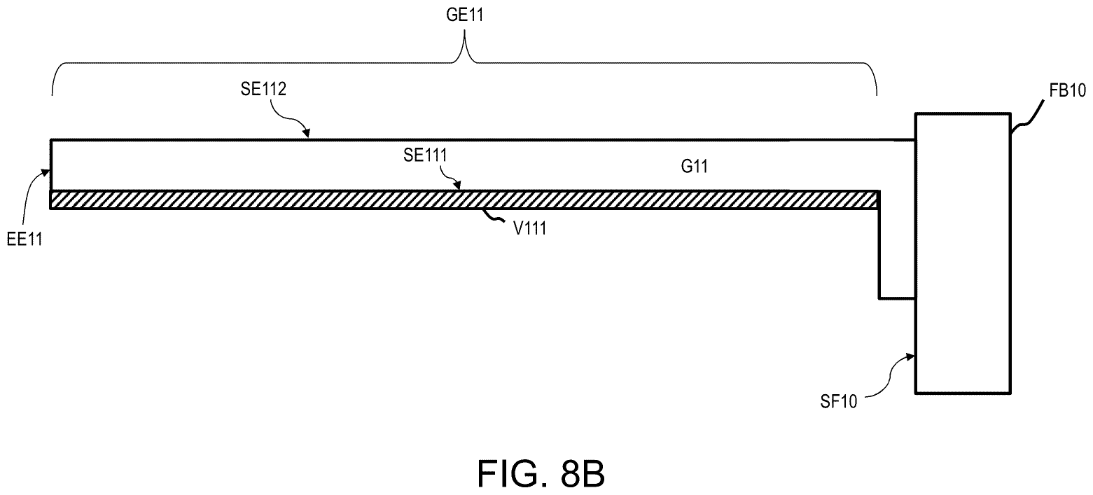

FIG. 8A is a side view schematic diagram depicting a signal shielding structure disposed on an outer of a first side of a first grounding pin to cover completely and connect all the layers of the first grounding pin according to an example embodiment of the present invention. FIG. 8B is a top view schematic diagram depicting a signal shielding structure disposed on an outer of a first side of a first grounding pin to cover completely and connect all the layers of the first grounding pin according to an example embodiment of the present invention.

Referring also to FIGS. 8A, 8B, in this embodiment, a signal shielding structure Viii is disposed on the outer of the first side SE111 of that first grounding pin G11 and completely covers and electrically conducts on each first sides SE111 of all of the layers L11(1)˜L11(4) of that first grounding pin G11. The horizontal projecting area of the signal shielding structure V111 toward that first side SE111 is equal to that horizontal projecting area of the plurality of layers toward that first side SE111.

That is, the present embodiment differs from the embodiments of FIGS. 6A, 6B and the embodiments of FIGS. 7A, 7B in that in the present embodiment, the signal shielding structure V111 is, for example, a metal sheet structure that completely covers the first side SE111 to maximize signal shielding effect.

It should be noted that in the above embodiment, the beginning side of the extended end GE11 of the grounding pin is connected to that first surface SF10 of the connector body FB10, and no signal shielding structure is disposed/provided on the end side EE11 of that extended end GE11.

In summary, the gold finger connector and the memory storage device provided in this example embodiment includes a connector body; a plurality of grounding pins; and a plurality of signal shielding structures, wherein the plurality of grounding pins are disposed on the first surface of the connector body, wherein each grounding pin has a plurality of layers. The plurality of signaling shielding structures disposed on the outer of a side of the extension portion of the plurality of grounding pins, and electrically conducting the plurality of layers of the grounding pins, so as to suppress electrical interference between neighboring pins on gold finger connectors.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A gold finger connector, comprising:
connector body;
a plurality of grounding pins disposed on a first surface of the connector body, wherein each grounding pin has a plurality of layers; and
at least one first signal shielding structure, disposed on a first grounding pin of the plurality of grounding pins,
wherein the at least one first signal shielding structure is connected to an outer of a first side of an extension portion of the first grounding pin and electrically conducts to at least two layers of the first grounding pin.

2. The gold finger connector of claim 1, wherein the first side faces a second side of an extension portion of a second grounding pin of the plurality of grounding pins, wherein at least one second signal shielding structure is disposed on the second grounding pin, is connected to an outer of the second side of the second grounding pin, and electrically conducts at least two layers of the second grounding pin.

3. The gold finger connector of claim 2, wherein the gold finger connector further comprises a plurality of signaling pins disposed on the first surface of the connector body for transmitting data signals, wherein a first signaling pin of the plurality of signaling pins is disposed between the first grounding pin and the second grounding pin.

4. The gold finger connector of claim 3, wherein a first side of the first signaling pin is faced by the second side, on which the at least one second signal shielding structure is disposed, of the second grounding pin, and a second side of the first signaling pin is faced by the first side, on which the at least one first signal shielding structure is provided, of the first grounding pin.

5. The gold finger connector of claim 3, wherein at least one third signaling shielding structure is disposed on an outer of a further first side, opposite to the first side, of the first grounding pin.

6. The gold finger connector of claim 1, wherein the at least one first signal shielding structure electrically conducts all layers of the first grounding pin.

7. The gold finger connector as in claim 1, wherein a plurality of first signaling shielding structures are disposed on the outer of the first side of the first grounding pin to electrically conduct a plurality of layers in different groups of the layers of the first grounding pin.

8. The gold finger connector of claim 1, wherein each of the at least one first signal shielding structure is a metal structure and comprises a first metal stick and a second metal stick, wherein the first metal stick electrically conducts partial layers of the plurality of layers, wherein the second metal stick electrically conducts a further partial layers of the plurality of layers and connects at least two conduction holes disposed at the further partial layers of the first grounding pin.

9. The gold finger connector of claim 8, wherein an upper surface of the first metal stick is flush with an upper surface of an uppermost layer of the plurality of layers, and extends downwardly to connect to the outer of the first side of other layers of the partial layers, wherein a lower surface of the first metal stick is flush with a lower surface of the lowermost layer of the partial layers.

10. The gold finger connector of claim 1, wherein the plurality of layers of the first grounding pin are layer-shape pieces parallel to each other, wherein the plurality of layers are vertically projected within same projecting area, and wherein the first side of the first grounding pin comprises a first side of each of the plurality of layers, wherein the at least one first signal shielding structure is one or more metal sticks connected to the outer of the first side of the plurality of layers, and vertical projections of the at least one first signal shielding structure are not within the projecting area of the plurality of layers.

11. The gold finger connector of claim 1, wherein the at least one first signal shielding structure is a metal structure that covers a first side of each of the plurality of layers, and does not extend outside a horizontal projecting range of the plurality of layers toward the first side.

12. The gold finger connector of claim 11, wherein the metal structure completely covers the first side of each of the plurality of layers, and a horizontal projecting area of the metal structure toward the first side is equal to the horizontal projecting range of the plurality of layers toward the first side.

13. A memory storage device that includes:
a gold finger connector;
a rewritable non-volatile memory modules; and
a memory control circuit unit electrically connected to the gold finger connector and the rewritable nonvolatile memory module, wherein the gold finger connector comprises:
a connector body;
a plurality of grounding pins provided on a first surface of the connector body, wherein each grounding pin has a plurality of layers; and
at least one first signal shielding structure, disposed on a first grounding pin of the plurality of grounding pins,
wherein the at least one first signal shielding structure is connected to an outer of a first side of an extension portion of the first grounding pin and electrically conducts to at least two layers of the first grounding pin.

14. The memory storage device of claim 13, wherein the first side faces a second side of an extension portion of a second grounding pin of the plurality of grounding pins, wherein at least one second signal shielding structure is disposed on the second grounding pin, is connected to an outer of the second side of the second grounding pin, and electrically conducts at least two layers of the second grounding pin.

15. The memory storage device of claim 14, wherein the gold finger connector further comprises a plurality of signaling pins disposed on the first surface of the connector body for transmitting data signals, wherein a first signaling pin of the plurality of signaling pins is disposed between the first grounding pin and the second grounding pin.

16. The memory storage device of claim 15, wherein a first side of the first signaling pin is faced by the second side, on which the at least one second signal shielding structure is disposed, of the second grounding pin, and a second side of the first signaling pin is faced by the first side, on which the at least one first signal shielding structure is provided, of the first grounding pin.

17. The memory storage device of claim 15, wherein at least one third signaling shielding structure is disposed on an outer of a further first side, opposite to the first side, of the first grounding pin.

18. The memory storage device of claim 13, wherein the at least one first signal shielding structure electrically conducts all layers of the first grounding pin.

19. The memory storage device of claim 13, wherein a plurality of first signaling shielding structures are disposed on the outer of the first side of the first grounding pin to electrically conduct a plurality of layers in different groups of the layers of the first grounding pin.

20. The memory storage device of claim 13, wherein each of the at least one first signal shielding structure is a metal structure and comprises a first metal stick and a second metal stick, wherein the first metal stick electrically conducts partial layers of the plurality of layers, wherein the second metal stick electrically conducts a further partial layers of the plurality of layers and connects at least two conduction holes disposed at the further partial layers of the first grounding pin.

21. The memory storage device of claim 20, wherein an upper surface of the first metal stick is flush with an upper surface of an uppermost layer of the plurality of layers, and extends downwardly to connect to the outer of the first side of other layers of the partial layers, wherein a lower surface of the first metal stick is flush with a lower surface of the lowermost layer of the partial layers.

22. The memory storage device of claim 13, wherein the plurality of layers of the first grounding pin are layer-shape pieces parallel to each other, wherein the plurality of layers are vertically projected within same projecting area, and wherein the first side of the first grounding pin comprises a first side of each of the plurality of layers, wherein the at least one first signal shielding structure is one or more metal sticks connected to the outer of the first side of the plurality of layers, and vertical projections of the at least one first signal shielding structure are not within the projecting area of the plurality of layers.

23. The memory storage device of claim 13, wherein the at least one first signal shielding structure is a metal structure that covers a first side of each of the plurality of layers, and does not extend outside a horizontal projecting range of the plurality of layers toward the first side.

24. The memory storage device of claim 23, wherein the metal structure completely covers the first side of each of the plurality of layers, and a horizontal projecting area of the metal structure toward the first side is equal to the horizontal projecting range of the plurality of layers toward the first side.
